(19) United States
(12) Patent Application Publication
(10) Pub. No.: US 2009/0263977 A1
(43) Pub. Date: Oct. 22, 2009

(54) SELECTIVE FUNCTIONALIZATION OF DOPED GROUP IV SURFACES USING LEWIS ACID/LEWIS BASE INTERACTION

(76) Inventors: Elena V. Rogojina, Los Altos, CA (US); Maxim Kelman, Mountain View, CA (US); Anthony Young Kim, Cupertino, CA (US)

Correspondence Address: Foley & Lardner LLP, 150 East Gilman Street, Madison, WI, 53701-1497, US

(21) Appl. No.: 12/104,028

(22) Filed: Apr. 16, 2008

(51) Int. Cl. H01L 21/312

(52) U.S. Cl. 438/765; 257/E21.259

(57) ABSTRACT

A method of selectively attaching a capping agent to a Group IV semiconductor surface is disclosed. The method includes providing the Group IV semiconductor surface, the Group IV semiconductor surface including a set of covalently bonded Group IV semiconductor atoms and a set of surface boron atoms. The method also includes exposing the set of boron atoms to a set of capping agents, each capping agent of the set of capping agents having a central atom and a set of functional groups, wherein the central atom includes at least a lone pair of electrons; wherein a complex is formed between at least some surface boron atoms of the set of surface boron atoms and the central atom of at least some capping agents of the set of capping agents.

### FIELD OF DISCLOSURE

This disclosure relates in general to semiconductors and in particular to the selective functionalization of doped Group IV semiconductor surfaces.

### BACKGROUND

Semiconductors form the basis of modern electronics. Possessing physical properties that can be selectively modified and controlled between conduction and insulation, semiconductors are essential in most modern electrical devices (e.g., computers, cellular phones, photovoltaic cells, etc.). Group IV semiconductors generally refer to those first four elements in the fourth column of the periodic table: carbon, silicon, germanium and tin.

The ability to deposit semiconductor materials using non-traditional semiconductor technologies such as printing may offer a way to simplify and hence reduce the cost of many modern electrical devices (e.g., computers, cellular phones, photovoltaic cells, etc.). Like pigment in paint, these semiconductor materials are generally formed as microscopic particles, such as nanoparticles, and temporarily suspended in a colloidal dispersion that may be later deposited on a substrate.

Nanoparticles are generally microscopic particles with at least one dimension less than 100 nm. In comparison to a bulk material (>100 nm) which tends to have constant physical properties regardless of its size (e.g., melting temperature, boiling temperature, density, conductivity, etc.), nanoparticles may have physical properties that are size dependent, such as a lower sintering temperature.

The nanoparticles may be produced by a variety of techniques such as evaporation (S. Ijima, Jap. J. Appl. Phys. 26, 357 (1987)), gas phase pyrolysis (K. A Littau, P. J. Szajowski, A. J. Muller, A. R. Kortan, L. E. Brus, J. Phys. Chem. 97, 1224 (1993)), gas phase photolysis (J. M. Jasinski and F. K. LeGoues, Chem. Mater. 3, 989 (1991)), electrochemical etching (V. Petrova-Koch et al., Appl. Phys. Lett. 61, 943 (1992)), plasma decomposition of silanes and polysilanes (H. Takagi et al, Appl. Phys. Lett. 56, 2379 (1990)), high pressure liquid phase reduction-oxidation reaction (J. R. Heath, Science 258, 1131 (1992)), etc.

A colloidal dispersion is a type of homogenous mixture consisting of two separate phases. A colloidal dispersion (or ink) generally consists of a continuous phase (such as a solvent), and a dispersed phase (generally particles under 1 um in diameter). The continuous phase must be compatible with the surface of the material to be dispersed. For example, carbon black particles (non-polar) tend to be easily dispersed in a hydrocarbon solvent (non-polar), whereas silica particles (polar) tend to be easily dispersed in alcohol (polar).

Polarity generally refers to the dipole-dipole intermolecular forces between the slightly positively charged end of one molecule to the negative end of another or the same molecule. However, semiconductor particles tend to be non-polar, and hence lyophobic (or solvent fearing).

It is often of benefit to functionalize semiconductor surfaces by the addition of capping agents in order to improve compatibility with the media and simplify and/or enable manufacturing processes. In general, a capping agent or ligand is a set of atoms or groups of atoms bound to a “central atom” in a polyatomic molecular entity. The capping agent is selected for some property or function not possessed by the underlying surface to which it may be attached.

Consequently, a common method of dispersing a non-polar particle in a polar solvent is through modification of the particle surface, often with an ionizable (or polar organic) capping agent or ligand. For example, ionizable functional groups, such as carboxyl, amino, sulfonate, etc. or polymeric forms thereof, are often covalently attached to non-polar particles in order to add charge and allow repulsive electrostatic forces aid in the dispersion of the particles in the solvent. Alternatively in the case of apolar solvents, non-ionizable organic groups, highly compatible with the solvent, may be covalently grafted to the particles to aid dispersion and impart stability via solvation forces. Examples of non-ionizable organic groups include different geometry hydrocarbons (e.g., alkanes, alkenes, alkynes, cycloalkanes, alkadienes, etc.).

In addition, once dispersed, these particles will tend to stay suspended and avoid agglomeration if the repulsive electrostatic and/or solvation forces are sufficiently higher than the normally attractive Van der Waals forces. If the repulsive barrier to Van der Waals interactions is higher than about 15 kT, then Brownian motion of the particles is too low to cause appreciable agglomeration and the dispersion is considered stable. This balance of energies is the essence of Detjaguin-Landau-Verwey-Overbeek (DLVO) theory used to explain stability of electrostatically-stabilized colloids.

Capping agents can also attach antimicrobial molecules (e.g., polycationic (quaternary ammonium), gentamycin, penicillin, etc.) on a Group IV semiconductor surface in order to protect people from microbial infection. For example, Group IV materials with antimicrobial capping agents may be used for making clothing that can be more safely worn in contaminated environments.

However, in these and other uses, it is generally difficult to selectively attach the capping agent to the Group IV semiconductor surface, since the surface's chemical structure tends to be uniform. Consequently, the capping agent tends to attach to all available surface sites reactive toward it, completely covering the surface. This may be problematic for applications which require a direct access to the Group IV semiconductor surface. For example, an excessive amount of capping agents may inhibit sintering. Sintering is generally a method for making objects from powder by heating the particles below their melting point until they adhere to each other.

In addition, once attached to the Group IV semiconductor surface, capping ligands may be difficult to remove and may consequently interfere with the surface functionality. For example, many capping agents (once deposited and sintered) may act as contaminants which detrimentally affect the electrical characteristics of the semiconductor particle.

In view of the foregoing, there is desired a method of selectively capping a semiconductor surface such that it still retains original surface properties.

### SUMMARY

The invention relates, in one embodiment, to a method of selectively attaching a capping agent to a Group IV semiconductor surface. The method includes providing the Group IV semiconductor surface, the Group IV semiconductor surface including a set of covalently bonded Group IV semiconductor atoms and a set of surface boron atoms. The method also includes exposing the set of boron atoms to a set of capping agents, each capping agent of the set of capping agents having a central atom and a set of functional groups, wherein the central atom includes at least a lone pair of electrons; wherein a complex is formed between at least some surface boron atoms of the set of surface boron atoms and the central atom of at least some capping agents of the set of capping agents.

The invention relates, in one embodiment, to a method of selectively attaching a capping agent to a Group IV semiconductor surface. The method includes providing the Group IV semiconductor surface, the Group IV semiconductor surface including a set of covalently bonded Group IV semiconductor atoms and a set of surface phosphorous atoms. The method further includes exposing the set of phosphorous atoms to a set of capping agents, each capping agent of the set of capping agents having a central atom and a set of functional groups, wherein the central atom includes at least a empty electron orbital; wherein a complex is formed between at least some surface phosphorous atoms of the set of surface phosphorous atoms and the central atom of at least some capping agents of the set of capping agents.

### BRIEF DESCRIPTION OF THE DRAWINGS

The present invention is illustrated by way of example, and not by way of limitation, in the figures of the accompanying drawings and in which like reference numerals refer to similar elements and in which:

FIGS. 1A-B show a set of simplified diagrams of Lewis acid/Lewis base complexation, in accordance with the invention;

FIG. 2 shows a simplified diagram of a hydrogen-passivated Group IV semiconductor surface, such as a silicon particle or silicon nanoparticle, in accordance with the invention;

FIG. 3 shows a simplified diagram of a Group IV semiconductor surface, such as a silicon particle or silicon nanoparticle, with the addition of a dopant, in accordance with the invention;

FIGS. 4A-C show a set of simplified diagrams of an amine capping agent, in accordance with the invention;

FIGS. 5A-C show a set of simplified diagrams of an phosphine capping agent, in accordance with the invention;

FIGS. 6A-C show a set of simplified diagrams of an ether capping agent and an alcohol capping agent, in accordance with the invention;

FIGS. 7A-C show a set of simplified diagrams of a sulfide capping agent and a thiol capping agent, in accordance with the invention;

FIG. 8 shows a simplified particle's size distribution diagram of the dispersion effectiveness of various capping agents, in accordance with the invention;

FIG. 9 shows FTIR spectra of dried films deposited from several colloidal dispersions of silicon particles treated with various capping agents, in accordance with the invention; and

FIG. 10 shows a simplified diagram of conductivity for a set of densified films made from various capped and uncapped silicon nanoparticles, in accordance with the invention

### DETAILED DESCRIPTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

As previously described, current methods of attaching a capping agent to a Group IV semiconductor surfaces are not selective because of non-selective surface reactivity and may be problematic for specific applications. In an advantageous manner, incorporation of atoms other than Group IV on a semiconductor surface may create these necessary selective anchor points. For example, Group III or Group V atoms, which are often used for semiconductor doping, may be incorporated. Dopants are added to a semiconductor in order to alter its electrical behavior. The addition of relatively small amounts of dopants (<1%), can change the electrical conductivity of the semiconductor by many orders of magnitude by increasing the amount of electrically charged carriers. Conduction generally refers to the movement of electrically charged carriers, such as electrons or holes (i.e., lack of electrons). Depending on the kind of impurity, a doped region of a semiconductor can have more electrons (n-type) or more holes (p-type). A typical p-type dopant is boron (Group III), which lacks an outer-shell electron compared with silicon and thus tends to contribute a hole to the valence energy band. In contrast, a typical n-type dopant is phosphorous (Group V), which has an additional outer-shell electron compared with silicon and thus tends to contribute an electron to the conduction energy band.

Boron (and other Group III) atoms with three electrons in outer shell in sp3 configuration carry one empty electron orbital which acts as electron acceptor. In contrast, Phosphorous (and other Group V) atoms with five outer shell electrons, in sp3 configuration have one electron orbital with a pair of electrons, which are available for electron donation. Because of such specific electron configurations, Group III atoms exhibit Lewis acid properties (acceptor of electron pair), while Group V atoms act as Lewis bases (donor of electron pair). Consequently, they can be used as selective attachment sites for capping agents with Lewis base/Lewis acid properties.

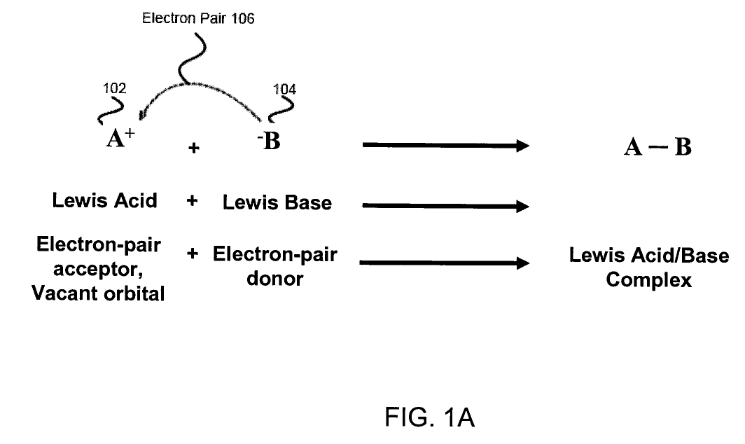

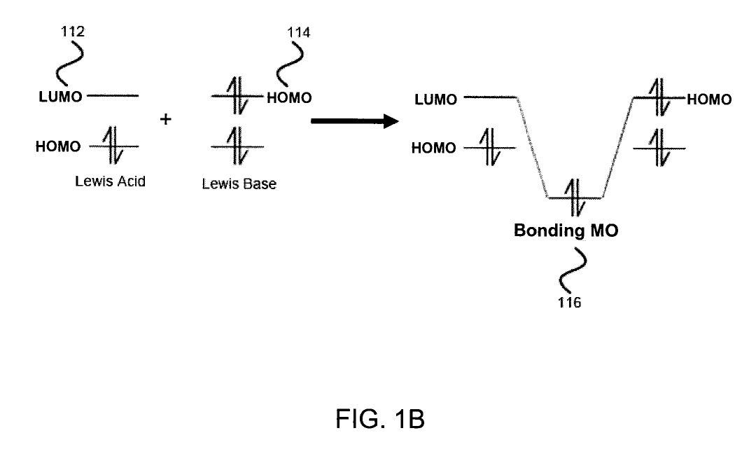

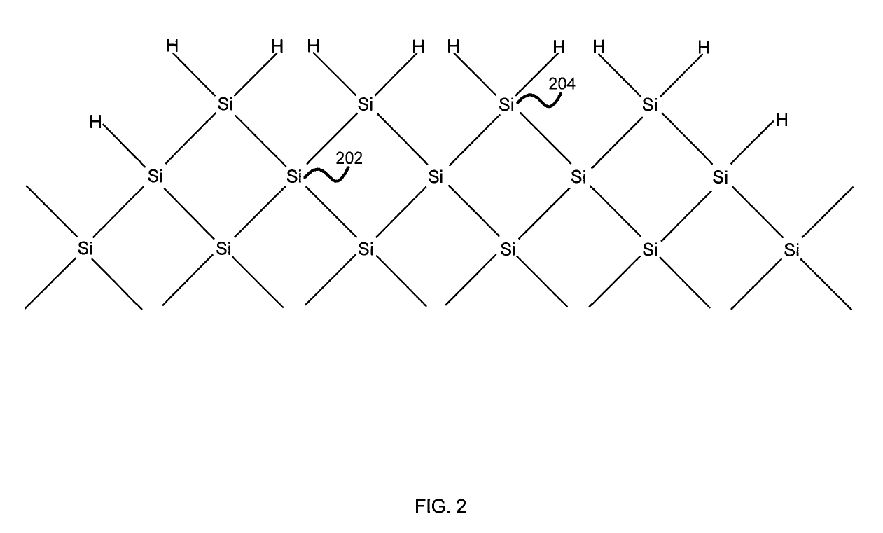

Referring now to FIGS. 1A-B, a set of simplified diagrams is shown of Lewis acid/Lewis base complexation, in accordance with the invention. FIG. 1 shows the interaction using Lewis theory, while FIG. 1B shows the interaction using FMO (frontier molecular orbital) theory. In general, complexation is the formation of complex chemical species by the coordination of groups of atoms termed ligands to a central ion. The ligand typically coordinates by providing a pair of electrons that forms an ionic or covalent bond to the central ion.

Referring to FIG. 1A, a complex is formed under Lewis theory when one-pair of electrons 106 moves from Lewis base 104 (the electron-pair donor) to the Lewis acid 102 (electron-pair acceptor) to give a two electron chemical bond. This bond may be a stronger covalent bond or a weaker complex bond.

Referring to FIG. 1B, the reaction of FIG. 1A is shown under FMO theory. Under FMO, the interaction between the reactants can be treated as the sum of the interactions between the frontier electron orbitals. That is, a stable molecular orbital 116 may be achieved between an electrons pair in the highest occupied molecular orbital of one atom (HOMO 114), usually a Lewis base, and the lowest unoccupied molecular orbital (LUMO 112) of another atom, usually a Lewis acid. In contrast, a LUMO-LUMO configuration is destabilizing, whereas a LUMO-LUMO interaction lacks electrons and thus will not form a complex.

Consequently, the inventors believe that capping agents with electron pair donors (tertiary amines, phosphines, ethers, alcohols, sulfides, thiols, etc.) may be used for selective attachment to Group III dopant atoms, whereas capping agents with electron pair acceptors (boranes, aluminum trichloride and organochlorides, etc.) may be used for selective attachment to Group V dopant atoms such as phosphorous.

Silicon is located in the periodic table immediately below carbon. It has the four electrons available in its outer shell for bonding (2 electrons in the 3s orbital and 2 electrons in the 3p orbital). The s and p orbitals hybridize to form four sp³ orbitals. This allows a lower energy state to be achieved in a silicon atom by filling all the s and p orbitals in the outer silicon shell (3s² and 3p⁶) when bonded to four of its neighbors. Thus, Si is tetravalent and forms tetrahedral compounds. Unlike carbon silicon does not form stable double bonds because of larger atom radius limiting overlap of two π-orbitals. In general, bonds with electronegative elements are stronger with silicon than with carbon.

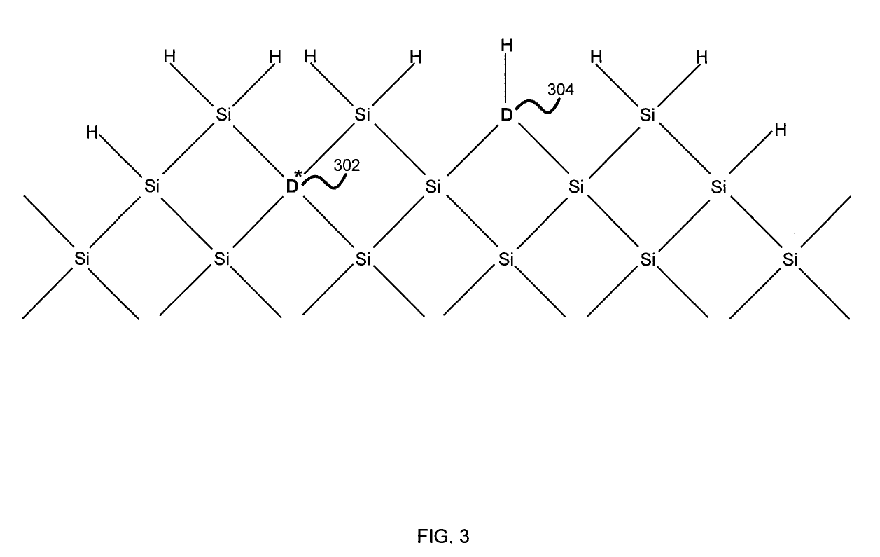

Referring now to FIG. 2, a simplified diagram of a hydrogen-passivated Group IV semiconductor surface, such as a silicon particle or silicon nanoparticle is shown. In general, the silicon particles may be produced in a plasma chamber, as well by other appropriate manufacturing techniques, such as evaporation (S. Ijima, Jap. J. Appl. Phys. 26, 357 (1987)), gas phase pyrolysis (K. A Littau, P. J. Szajowski, A. J. Muller, A. R. Kortan, L. E. Brus, J. Phys. Chem. 97, 1224 (1993)), gas phase photolysis (J. M. Jasinski and F. K. LeGoues, Chem. Mater. 3, 989 (1991);), electrochemical etching (V. Petrova-Koch et al., Appl. Phys. Lett. 61, 943 (1992)), plasma decomposition of silanes and polysilanes (H. Takagi et al, Appl. Phys. Lett. 56, 2379 (1990)), high pressure liquid phase reduction-oxidation reaction (J. R. Heath, Science 258, 1131 (1992)) and by refluxing the zintyl salt, KSi with excess silicon tetrachloride in a solvent of glyme, diglyme, or THF under nitrogen (R. A. Bley and S. M. Kauzlarich, J. Am. Chem. Soc., 118, 12461 (1996)).

Here, in internal lattice site 202 of nanoparticle or crystalline wafer, a silicon atom 202 is bonded to its four proximate silicon atom neighbors.

Similarly, on a surface lattice site 204 two Sp3 orbitals of silicon atom 204 used for bonding with neighboring silicon atoms and other two sp3 orbitals bound to neighboring hydrogen atoms. As previously described, these hydrogen atoms serve to passivate the silicon atom.

Referring now to FIG. 3, a simplified diagram of a Group IV semiconductor surface, such as a silicon particle or silicon nanoparticle, with the addition of a dopant. As previously described, dopants such as 302 are often added to alter the behavior of a semiconductor insulator to a conductor. Examples of p-type dopants are Group III elements such as B (boron), Ga (gallium), and In (indium). Examples of n-type dopant include Group V elements such as P (phosphorus), As (arsenic) and Sb (antimony). Depending on the underlying structure, dopant concentration is usually less than 1% of the total semiconductor volume.

Dopant atoms that are substitutionally positioned in a lattice, provide an additional electron (in the case of an n-type dopant) or the lack of an electron (or hole in the case of a p-type dopant) generally available for electrical current transport. For example, in the case of an n-type dopant, five outer shell electrons are available (2 electrons in the outer orbital and 3 electrons in the outer p orbital). As only four are needed to form Sp3 hybrid orbital bonds with neighboring atoms, such as Si or H, an additional unbonded electron is available. In contrast, in the case of a p-type dopant, three outer shell electrons are available (2 electrons in the outer s orbital and one electron in the outer p orbital). Again, as four are needed to form Sp3 hybrid orbital bonds with neighboring semiconductor atoms, but only three electrons are available, one of the bonds is only partially filled, leaving a hole. In general, non-surface substitutional dopant atoms physically are not available as selective anchor points for Lewis acid/Lewis base capping agents because the capping agent molecules are generally larger than the lattice structure spacing.

In contrast, surface substitutional dopant atoms, such as 304, are available as selective anchor point because they are accessible to the corresponding active atom of the capping agent. Here, R 304 is bonded to two semiconductor atoms, such as Si, and a passivating atom, such as H.

In the case of a p-type dopant (Group III atom), as previously described, three outer shell electrons are generally available. Here, the surface substitutional dopant in sp3 hybridization state has four sp3 orbitals: three bonding sp3 orbitals, each carrying one unpaired electron, and fourth non-bonding empty sp3 orbital. Consequently, Group III atom R 304 is bonded via three bonding sp3 orbitals with three neighboring atoms: two Si atoms and an H atom, leaving fourth empty sp3 orbital available to accept extra electron pair. Consequently, 304 may function like a Lewis acid when complexing with a Lewis base (electron pair donor).

By analogy, in the case of an n-type dopant (Group V atom), five outer shell electrons are generally available. Here, the surface substitutional dopant in sp3 hybridization state has four sp3 orbitals: three bonding sp3 orbitals, each carrying one unpaired electron, and fourth non-bonding sp3 orbital with a free electron pair available for electron donation. Thus, 304 may function like a Lewis base when complexing with a Lewis acid via donation of its free electron pair.

### Nitrogen-Based Molecules (Amines)

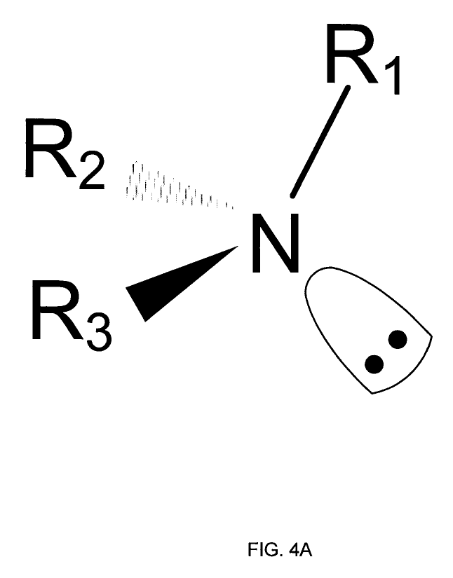

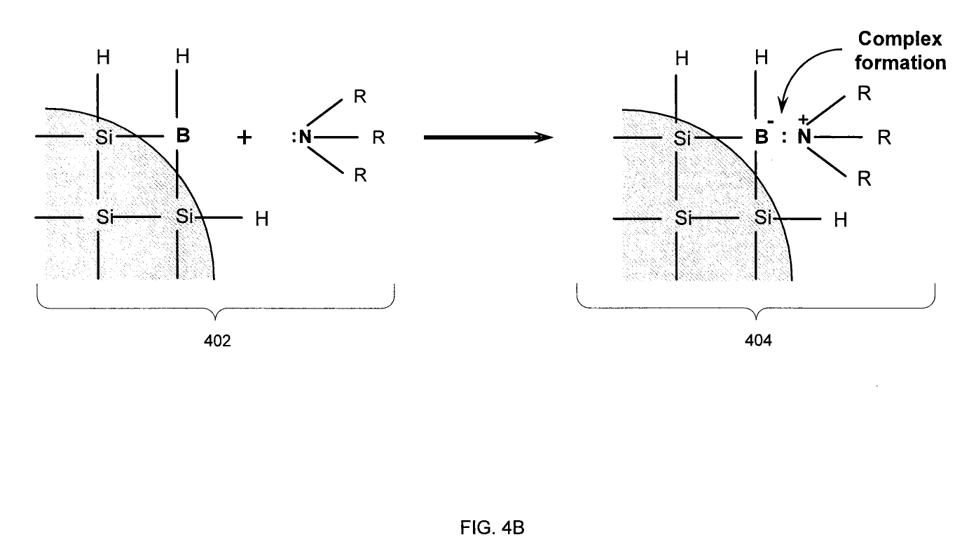

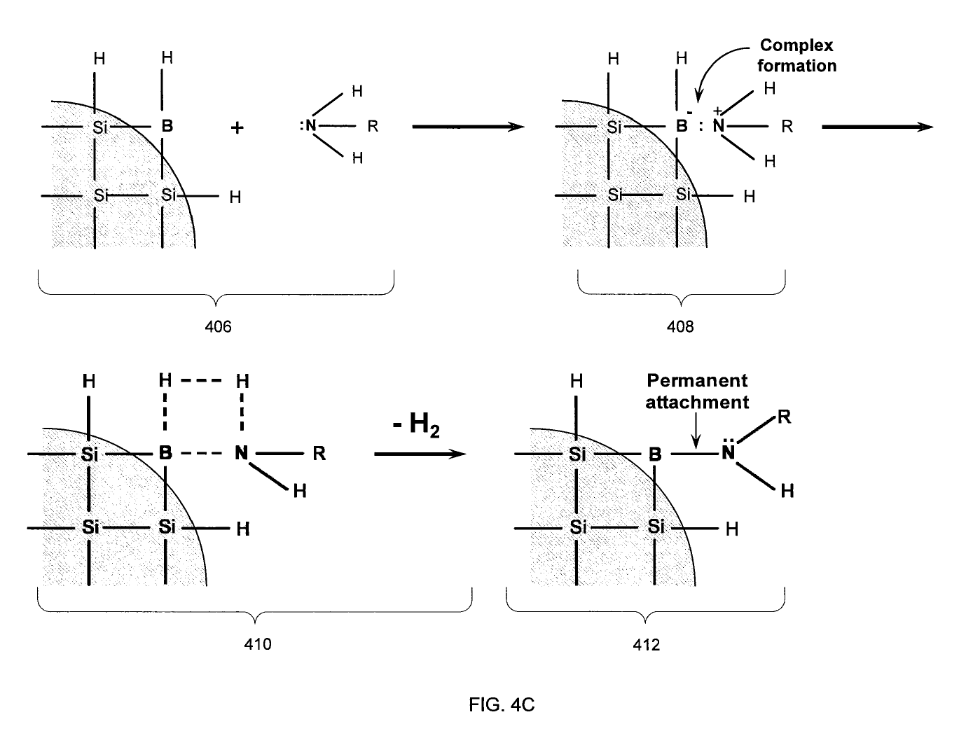

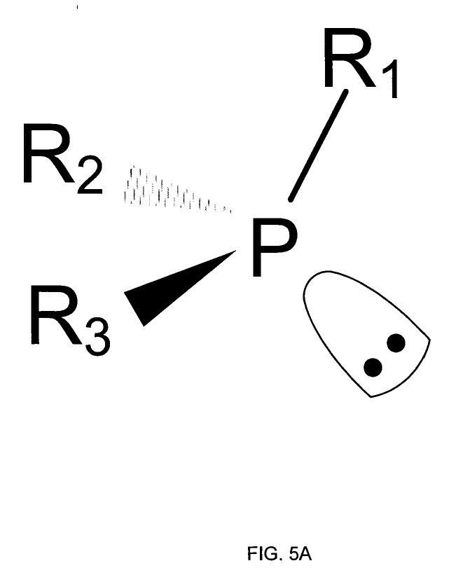

Referring now to FIGS. 4A-C, a set of simplified diagrams of an amine capping agent is shown, in accordance with the invention.

FIG. 4A shows a simplified diagram of an amine capping agent, in accordance with the invention. In general, amines are organic compounds and a type of functional group that contain nitrogen as the key atom. Structurally amines resemble ammonia, wherein one or more hydrogen atoms are replaced by organic substituents such as alkyl and aryl groups. From a bonding perspective, in analogy to ammonia amines function like Lewis bases in sp3 hybridization state. That is, via sp3 hybridization of nitrogen atom carrying two electrons in an s orbital and three electrons in a p orbital (five potential bonding electrons) four sp3 orbitals are created: three bonding orbitals, each with a single electron and the fourth orbital with an electron pair. Thus, nitrogen bonded via three sp3 orbitals with three functional groups, and fourth non-bonding sp3 orbital carries a free electron pair available for complex formation with an electron acceptor (Lewis Acid).

Aryl generally refers to any functional group or substituent derived from a simple aromatic ring. An alkyl is a univalent (or free) radical containing only carbon and hydrogen atoms where all carbon-carbon bonds are single bonds. Straight chain and branched alkyls form a homologous series with the general formula CₙH₂ₙ₊₁. Examples include methyl, CH₃ (derived from methane), isopropyl C₃H₇ (derived from isopropane), and butyl C₄H₉ (derived from butane). Cyclic alkyls (derived from cycloalkanes) have two less hydrogens and therefore general formula CₙH₂ₙ₋₁. Examples include cyclopentyl C₅H₉ and cyclohexyl C₆H₁₁ They are normally not found on their own but are found as part of larger branched chain or cyclic organic molecules. On their own they are free radicals and therefore extremely reactive.

FIG. 4B shows a simplified diagram of Lewis Acid-Lewis Base interaction between a tertiary amine (with non-hydrogen functional groups) and a surface substitutional boron atom, in accordance with the invention.

Initially, at 402, surface substitutional boron atom is exposed to the tertiary amine (all three hydrogen groups replaced with substitutants). Tertiary amines have three Alkyl/Aryl functional groups attached to the nitrogen atom via N—C bonds.

Consequently, at 404, the free electron pair of the fourth non-bonding sp3 orbital of Nitrogen atom is placed on the empty sp3 orbital of a Lewis base receptor Boron atom to form a complex, as described above. This electron pair is weakly shared between the nitrogen and the boron, rather than forming a much stronger covalent bond, since the binding energy of the complex is less than the binding energy (BE) with the tertiary amine functional groups: BE of B—N bond is 389 kJ/mol, while BE of N—C bond is 754.3 kJ/mol. Consequently, this complex bond between Boron and tertiary amine may be temporary. That is, the addition of energy, such as heat, will generally destroy the complex before breaking N—C bonds with the functional groups.

FIG. 4C shows a simplified diagram of Lewis Acid-Lewis Base interaction between a primary or secondary amine (with at least one hydrogen functional group) and a surface substitutional boron atom, in accordance with the invention.

Initially, at 406, a surface substitutional boron atom is exposed to the tertiary amine with at least one hydrogen functional group. As before, in 408 a complex begins to form between the nitrogen and the boron. However, binding energies of B—H and N—H groups (340 and 339 kJ/mol respectively) are lower than B—N bond (389 kJ/mol). Because of that soon thereafter at 410, these B—H and N—H bonds weaken, a hydrogen atom in a functional group interacts with a nearby surface hydrogen atom and form H₂ (hydrogen gas), which is subsequently vented. In the result, coordinate bond between Boron and Nitrogen at 412 becomes coordinate covalent bond, Thus, interaction of Boron with primary and secondary amines generally results into permanent attachment of the amine molecule.

### Phosphorous-Based Molecules (Phosphines)

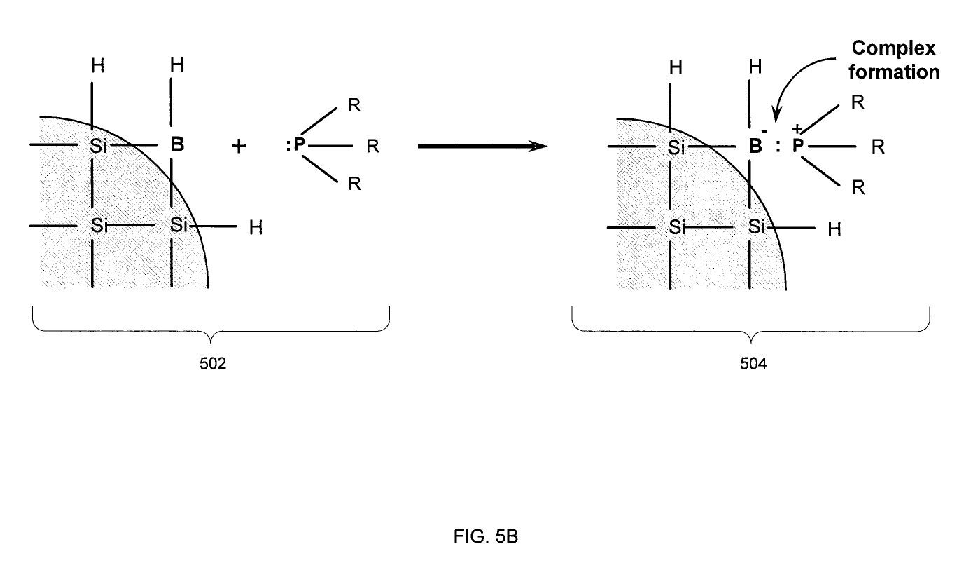

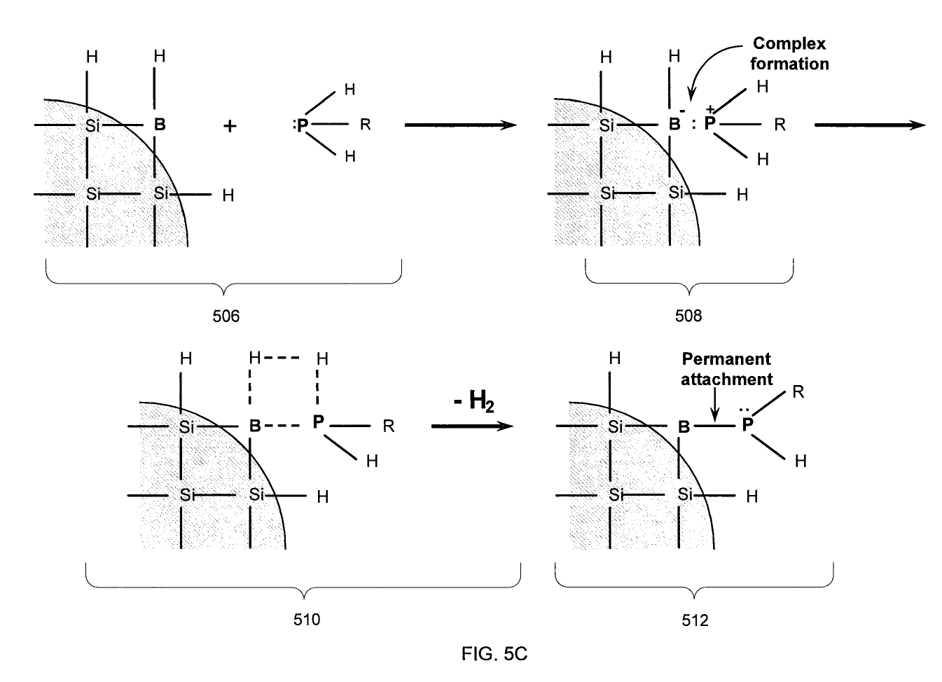

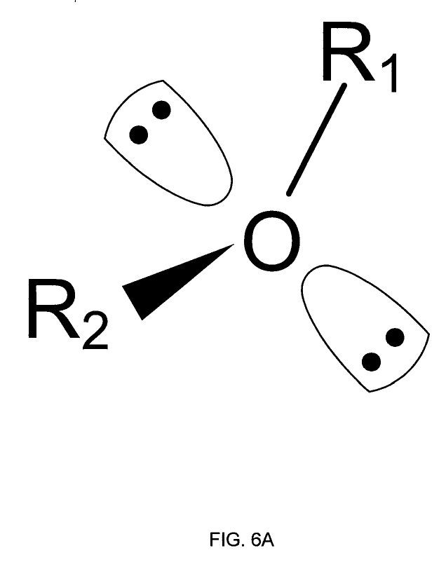

Referring now to FIGS. 5A-C, a set of simplified diagrams of a phosphine capping agent is shown, in accordance with the invention. In general, phosphines are organic compounds and a type of functional group that contain phosphorous as the key atom. In analogy to ammonia and amines, phosphines with sp3 hybridization state of phosphorus atom function like Lewis bases. That is, via sp3 hybridization of phosphorus atom carrying two electrons in an s orbital and three electrons in a p orbital (five potential bonding electrons) four sp3 orbitals are created: three bonding orbitals, each with a single electron and the fourth orbital with an electron pair. Thus, phosphorus bonded via three sp³ orbitals with three functional groups, and the fourth non-bonding sp3 orbital carries a free electron pair available for complex formation with electron acceptor (Lewis Acid).

FIG. 5A shows a simplified diagram of a tertiary phosphine capping agent, in accordance with the invention. Here the central phosphorus atom bonded via three sp³ orbitals with Alkyl/Aryl functional groups, and fourth non-bonding sp3 orbital carries free electron pair.

FIG. 5B shows a simplified diagram of Lewis Acid-Lewis Base interaction between a tertiary phosphine (with non-hydrogen functional groups) and a surface substitutional boron atom, in accordance with the invention.

Initially, at 502, surface substitutional boron atom is exposed to the tertiary phosphine. Consequently, at 504 the free electron pair of the fourth non-bonding sp3 orbital of Phosphorus atom is placed on the empty sp3 orbital of a Lewis base receptor Boron atom 504 to form a complex, as described above. This electron pair is weakly shared between the phosphorus and the boron, rather than forming a much stronger covalent bond, since the binding energy of the complex is less than the binding energy (BE) with the tertiary phosphine functional groups: BE of B—P bond is 346.9 kJ/mol, while BE of P—C bond is 513.4 kJ/mol. Consequently, this complex bond between Boron and tertiary phosphine may be temporary. That is, the addition of energy, such as heat, will generally destroy the complex before breaking P—C bonds with the functional groups.

FIG. 5C shows a simplified diagram of Lewis Acid-Lewis Base interaction between mono- and secondary phosphine (one or two hydrogen functional group) and a surface substitutional boron atom, in accordance with the invention.

Initially as before, at 506 a complex begins to form between the phosphorus and the boron. However, binding energies of B—H and P—H groups (340 and 297 kJ/mol respectively) are lower than B—P bond (346.9 kJ/mol). Because of that soon thereafter at 508, these B—H and P—H bonds weaken, a hydrogen atom in a functional group interacts with a nearby surface hydrogen atom and form H₂ (hydrogen gas), which is subsequently vented. In the result, coordinate bond between Boron and Phosphorus at 510 becomes coordinate covalent bond 512. Thus, interaction of Boron with primary and secondary phosphines results into permanent attachment of the phosphine molecule.

### Oxygen-Based Molecules (Ethers and Alcohols)

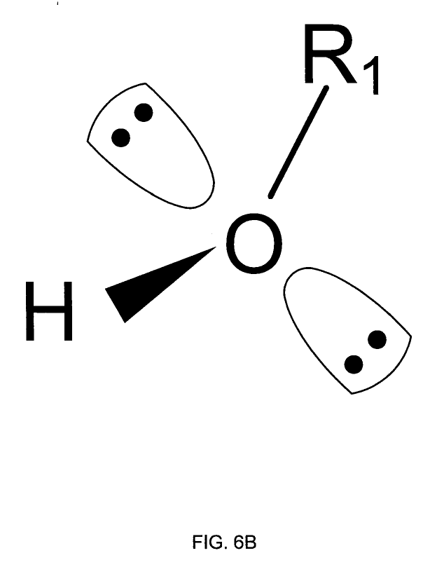

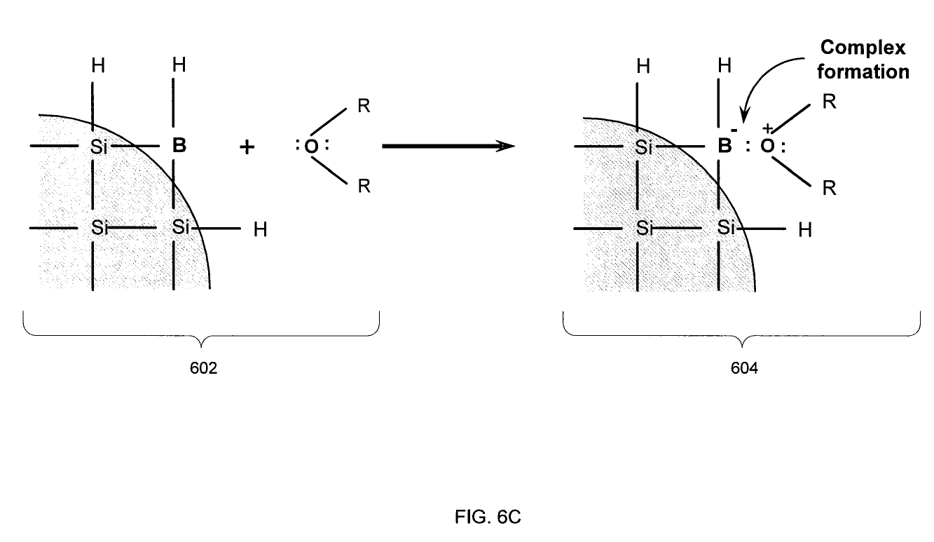

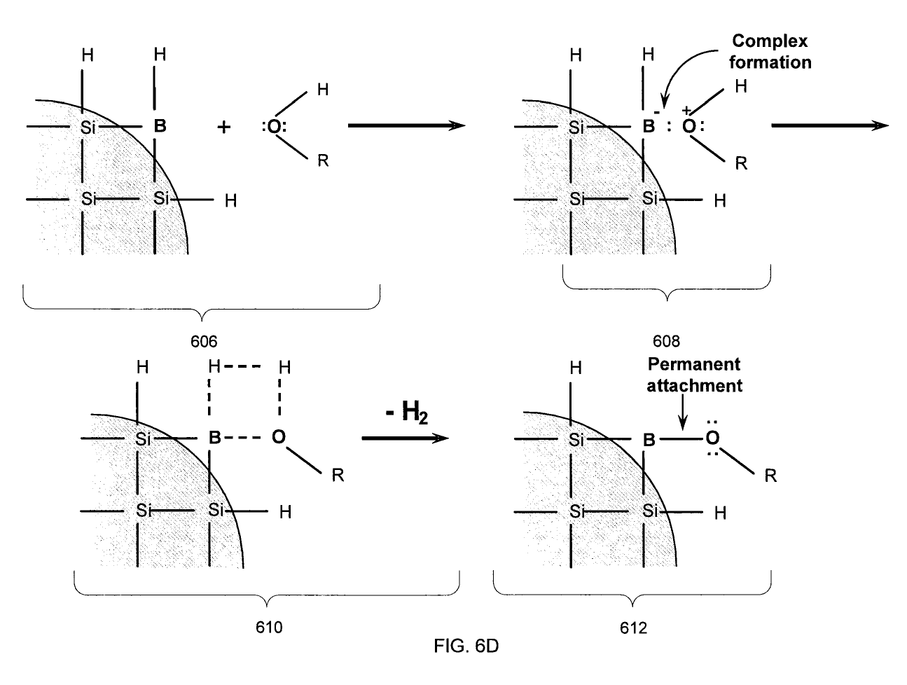

Referring now to FIGS. 6A-D, a set of simplified diagrams of ether and alcohol capping agents are shown, in accordance with the invention. Both compounds are analogs of water, where both (FIG. 6A) or only one hydrogen (FIG. 6B) respectively at the central oxygen atom are replaced by Alkyl/Aryl substitutant. In analogy to water molecule, with central oxygen atom being in sp3 hybridization state both classes of compounds function like Lewis bases. That is, oxygen atom has two electrons in an s orbital and four electrons in a p orbital. An sp3 hybridization results into four sp3 orbitals: two bonding sp3 orbitals, containing one unpaired electron each, and two non-bonding sp3 orbitals, each of them carry a pair of electrons. Thus, oxygen bonds via two sp³ orbitals with two functional groups, and the other two non-bonding sp3 orbitals carry free electron pairs available for complex formation with electron acceptor (Lewis Acid).

FIG. 6A shows a simplified diagram of an ether capping agent, in accordance with the invention. In general, an ether is a class of chemical compounds which contain a central oxygen atom connected to two (substituted) alkyl or aryl groups—of general formula R—O—R′.

FIG. 6B shows a simplified diagram of an alcohol capping agent, in accordance with the invention. In general, an alcohol is a class of chemical compounds which contain a central oxygen atom connected to one hydrogen and one alkyl or aryl groups—of general formula R—O—H.

FIG. 6C shows a simplified diagram of Lewis Acid-Lewis Base interaction between an ether and a surface substitutional boron atom, in accordance with the invention.

Initially, at 602, surface substitutional boron atom is exposed to the ether. Consequently, at 604, one of two free electron pairs may then form a complex with the empty sp3 orbital of a boron atom, as described above. This electron pair is weakly shared between the oxygen and the boron, rather than forming a much stronger covalent bond, since the binding energy of the complex is less than the binding energy (BE) with the ether functional groups: BE of B—O bond is 808.8 kJ/mol, while BE of O—C bond is 1076.5 kJ/mol. Consequently, this complex bond between Boron and the ether may be temporary. That is, the addition of energy, such as heat, will generally destroy the complex before breaking O—C bonds with the functional groups.

FIG. 6D shows a simplified diagram of Lewis Acid-Lewis Base interaction between an alcohol and a surface substitutional boron atom, in accordance with the invention.

Initially, at 606, a surface substitutional boron atom is exposed to the alcohol. As before, in 608 a complex begins to form between the oxygen and the boron. However, binding energies of B—H and O—H groups (340 and 427.6 kJ/mol respectively) lower than B—O bond (808.8 kJ/mol). Because of that soon thereafter at 608, these B—H and O—H bonds weaken, a hydrogen atom of a functional group interacts with a nearby surface hydrogen atom and form H₂ (hydrogen gas), which is subsequently vented. In the result, coordinate bond between Boron and oxygen at 610 becomes coordinate covalent bond 612. Thus, interaction of Boron with alcohols results into permanent attachment of the alcohol molecule

It has to be noted that although both alcohols and ethers are much more reactive toward B—H sites on H-passivated semiconductor surface than toward to the surface itself (Group IV-Group IV and Group IV—H bonds), they may interact with the surface itself, especially at elevated temperatures. Thus, ethers and alcohols are less selective Lewis Base reagents than amines and phosphines discussed above and sulfur compounds which will be discussed below.

### Sulfur-Based Molecules (Sulfides and Thiols)

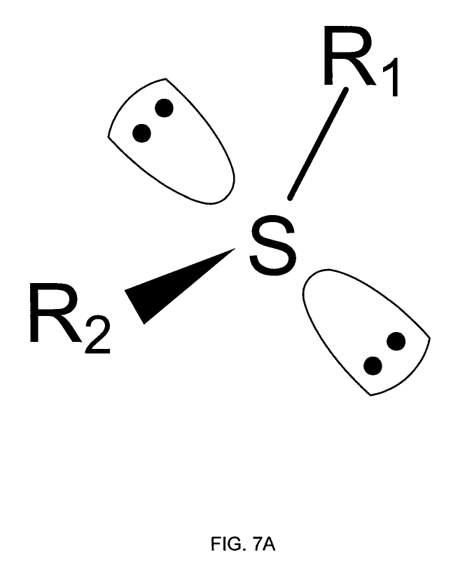

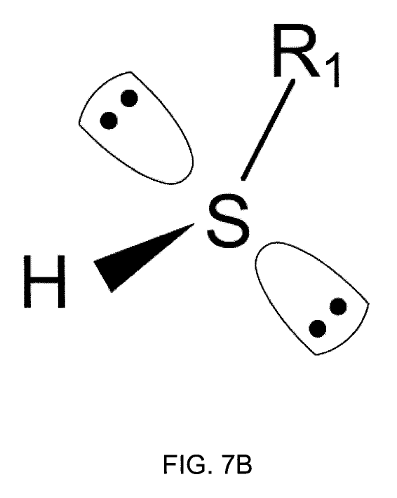

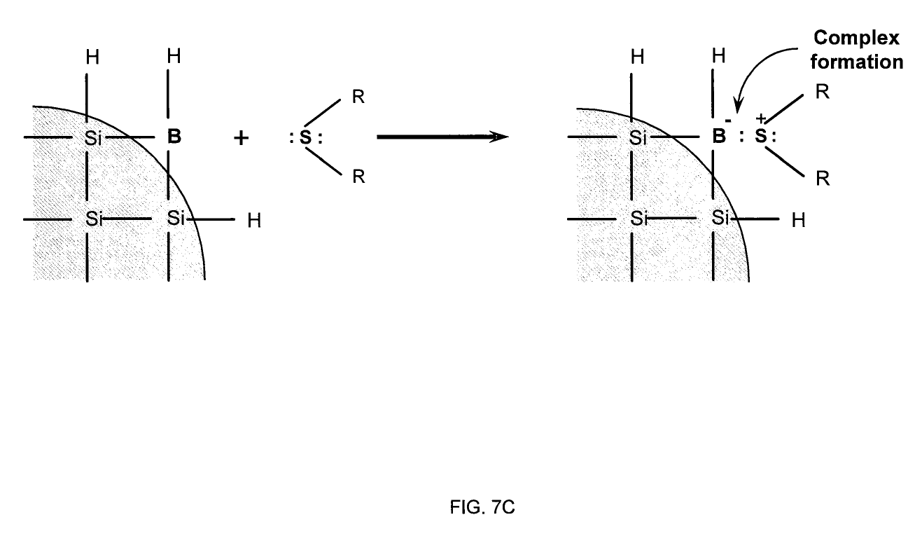

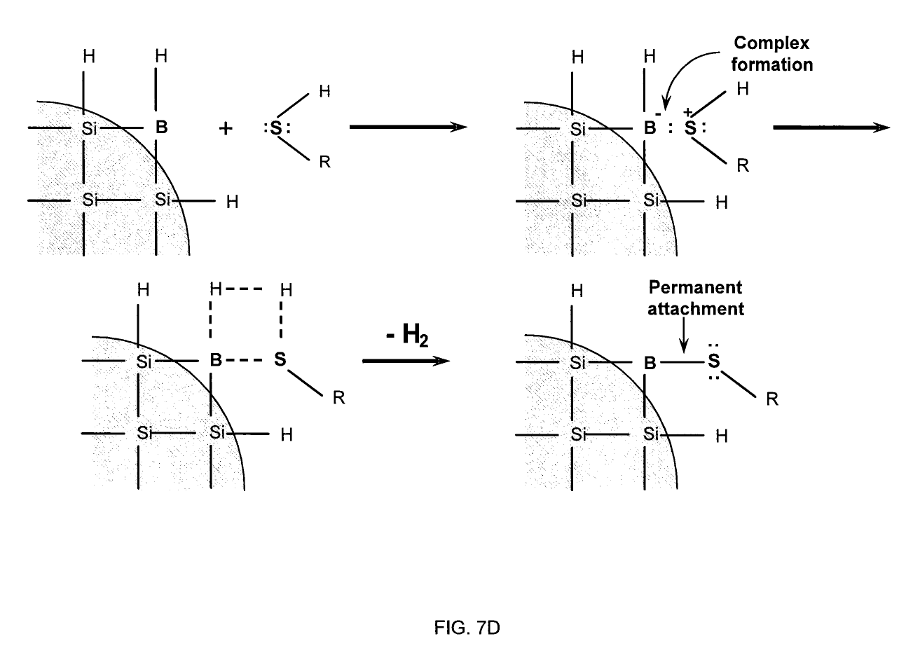

Referring now to FIGS. 7A-D, a set of simplified diagrams of a sulfide and a thiol capping agents are shown, in accordance with the invention. Both compounds are analogs of hydrogen sulfide H₂S, where both (FIG. 7A) or only one (FIG. 7B) hydrogen, respectively, at central sulfur atom replaced by Alkyl/Aryl substitutant. In analogy to H₂S molecule, with central sulfur atom being in sp3 hybridization state both classes of compounds function like Lewis bases. That is, sulfur atom has two electrons in an s orbital and four electrons in a p orbital. In general, sp3 hybridization results into four sp3 orbitals: two bonding sp3 orbitals, containing one unpaired electron each, and two non-bonding sp3 orbitals, each of them carrying a pair of electrons. Thus, sulfur bonded via two sp³ orbitals with two functional groups, and other two non-bonding sp3 orbitals carry free electron pairs available for complex formation with electron acceptor (Lewis Acid).

FIG. 7A shows a simplified diagram of a sulfide capping agent, in accordance with the invention. In general, a sulfide is a class of chemical compounds which contain a sulfur central atom connected to two alkyl or aryl groups—of general formula R—S—R′.

FIG. 7C shows a simplified diagram of Lewis Acid-Lewis Base interaction between a sulfide and a surface substitutional boron atom, in accordance with the invention.

Initially, at 702, surface substitutional boron atom is exposed to the sulfide.

Consequently, at 704, one of two free electron pairs may then form a complex with the empty sp3 orbital of a boron atom, as described above. This electron pair is weakly shared between the sulfur and the boron, rather than forming a much stronger covalent bond, since the binding energy of the complex is less than the binding energy (BE) with the sulfide functional groups: BE of B—S bond is 580.7 kJ/mol, while BE of S—C bond is 714.1 kJ/mol. Consequently, this complex bond between Boron and the sulfide may be temporary. That is, the addition of energy, such as heat, will generally destroy the complex before breaking S—C bonds with the functional groups.

FIG. 7D shows a simplified diagram of Lewis Acid-Lewis Base interaction between a thiol and a surface substitutional boron atom, in accordance with the invention.

Initially, at 606, a surface substitutional boron atom is exposed to the thiol. As before, in 708 a complex begins to form between the sulfur and the boron. However, binding energies of B—H and S—H groups (340 and 344.3 kJ/mol respectively) lower than B—S bond (580.7 kJ/mol). Because of that soon thereafter at 708, these B—H and S—H bonds weaken, a hydrogen atom of a functional group interacts with a nearby surface hydrogen atom and form H₂ (hydrogen gas), which is subsequently vented. In the result, coordinate bond between Boron and sulfur at 710 becomes coordinate covalent bond 712. Thus, interaction of Boron with thiols results into permanent attachment of the thiol molecule.

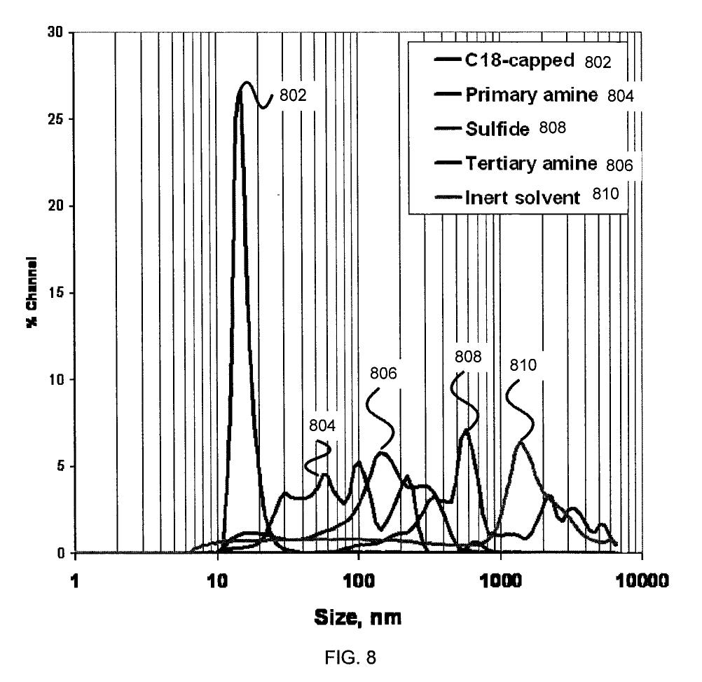

Referring now to FIG. 8, a simplified particle's size distribution diagram as measured by dynamic light scattering is showing the dispersion effectiveness of various capping agents, in accordance with the invention.

Generally, dynamic light scattering quantifies the particle size distribution by measuring the power spectrum of frequency shifted, scattered light arising from random thermal (Brownian) motion of the suspended particles. These frequency (Doppler) shifts are related to the particle velocities, where smaller particles generally have higher velocities and therefore larger Doppler shifts. In the heterodyne method employed here, a coherent laser light source is directed at the suspension of particles, and the frequency-shifted, back-scattered light due to particle motions is recombined with part of the incident, unshifted light. The resulting interference pattern relates to the distribution of Doppler shifts. Thus, particle size distribution is obtained by analysis of the detected heterodyne power spectrum.

Horizontal axis shows particle agglomerate size (average size for that bin or “channel”) in a logarithmic nanometer (nm) scale, while vertical axis shows % channel (e.g., the percentage of particles in the size range of that channel). In general, in colloidal dispersions of nanoparticles, the particles tend to form agglomerates in order to reduce their surface energy. Agglomerates may comprise relatively weak bonds between the nanoparticles (i.e., a potential energy minimum on the order of a few kT), and can be easily disassociated with the addition of small mechanical or thermal energy. Thus, in general, the larger the size of underlying nanoparticle, the larger the corresponding size of the agglomerate.

A first reference colloidal dispersion 802 is loaded with un-doped Si nanoparticles capped with a C₁₋₈ hydrocarbon. A second colloidal dispersion 804 loaded with boron-doped Si nanoparticles partially capped with a primary amine (i.e., an amine with a single non-hydrogen functional group and two hydrogen functional groups). A third colloidal dispersion 806 is loaded with boron-doped Si nanoparticles partially capped with a tertiary amine (i.e., an amine with a three non-hydrogen functional groups). A fourth colloidal dispersion 808 is loaded with boron-doped Si nanoparticles partially capped with a sulfide. And a fifth colloidal dispersion 810 is loaded with boron-doped Si nanoparticles in an inert solvent, and thus uncapped

Capping reagent is also a solvent for all these p-type particle's dispersions. Un-doped C18-capped particles are dispersed in chloroform. Inert solvent is a mixture of chloroform and benzene.] Particles and solvent(s) were mixed and the mixture was stirred for 30 min by stirring at room temperature followed by about a 15 min ultrasonic horn sonication at about 15% power. The colloidal dispersions (except the one in inert solvent) were further filtered through 5 micron Nylon filter.

In general, for a particle in a solvent, the percentage of capped surface area is substantially correlated to the degree of dispersability. That is, highly capped particles disperse well, while lightly capped or uncapped particles disperse poorly and tend to clump and precipitate out of the solvent.

In the first reference colloidal dispersion 802, in which C18 hydrocarbon capping ligands are attached to the silicon surface atoms in the nanoparticle, the dispersion quality is very good, with an average agglomerate size of about 11 nm corresponding to a single particle size. In contrast, in the fifth colloidal dispersion 810, in which uncapped nanoparticles are suspended in an inert solvent, the dispersion is poor, with an average agglomerate particle size of about 1100 nm. Consequently, second colloidal dispersion 804, third colloidal dispersion 806, and fourth colloidal dispersion 808, in which the capping agents complex with surface substitutional boron atoms, dispersability is better than with the fifth non-capped inert solvent colloidal dispersion, but worse than the first C-18 capped solvent colloidal dispersion. Among themselves, second colloidal dispersion 804 with primary amine partial capping is characterized by smaller average agglomerate size than third colloidal dispersion 806 and fourth colloidal dispersion 808.

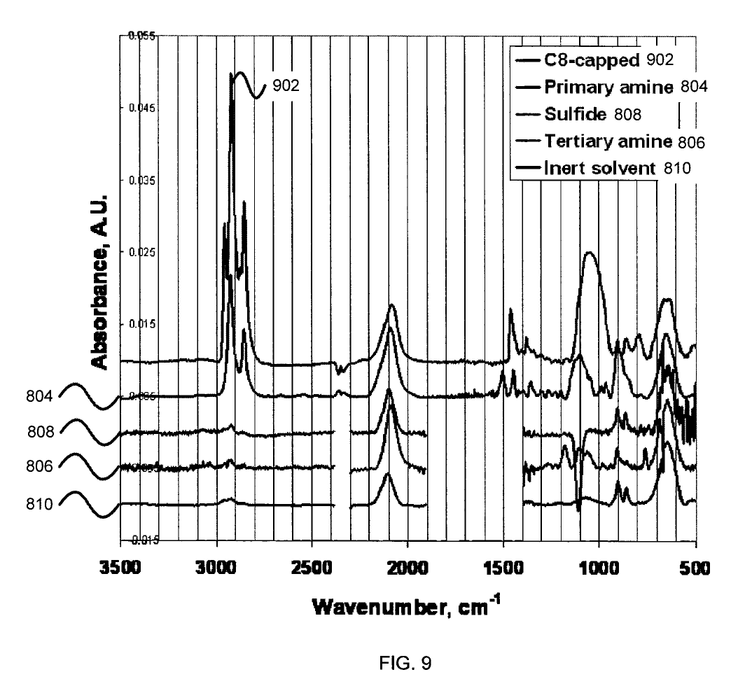

Referring now to FIG. 9, FTIR spectra of dried films deposited from several colloidal dispersions of Silicon particles treated with various capping agents are presented, in accordance with the invention.

In general, Fourier transform infra-red (FTIR) spectroscopy is a measurement technique whereby spectra are collected based on measurements of the temporal coherence of a radiative source, using time-domain measurements of the electromagnetic radiation or other type of radiation (shown as wavenumber on the horizontal axis). At certain resonant frequencies characteristic of the specific sample, the radiation will be absorbed (shown as absorbance A.U.) on the vertical axis) resulting in a series of peaks in the spectrum, which can then be used to identify the samples. A set of peaks in the range 2850-3000 cm⁻¹ is representative of a hydrocarbon bonds present in capping ligands on the particle's surface.

Here, a set of porous thin film compacts were formed by depositing a colloidal dispersion of p-type silicon nanoparticles on FTIR transparent substrates. These thin films were then baked at about 60-350° C. from 5 to 30 minutes, in order to remove any remaining solvent and complexed capping agents. Five sets of porous compacts in total were made: C8 hydrocarbon capped 902, primary amine capped 804, tertiary amine capped 806, sulfide capped 808, and non-capped 810. These porous compacts were then measured using FTIR as described above.

FTIR spectra of dried films printed from several colloidal dispersions were normalized by Si—Si signal intensity (˜640 cm−1). Thus, the intensity of hydrocarbon peaks in the range 2850-3000 cm⁻¹ becomes a reflection of the degree of permanent capping with various capping agents. As it can be seen, the C8 hydrocarbon capped 902 and primary amine capped 804 show set of intense peaks in the range 2850-3000 cm⁻¹ characteristic of hydrocarbon absorption, whereas for the remaining dry films 806, 808 and 810 this characteristic organic peak is negligible intensity. It is believed that in dispersion 902 the surface of particles is uniformly capped with C8 hydrocarbons chains via permanent covalent bonding. Dried film deposited from this dispersion has most intense hydrocarbon peak. For dispersion 804, where primary amine was applied and also formed permanent covalent bonds with the surface of particles (because of hydrogen gas formation as previously described), the hydrocarbon peak was observed as well. However it has 3-4 times lower intensity than the one for C8 capped particles. This difference in hydrocarbon peak intensities confirms partial capping of Si nanoparticles surface with primary amine, which selectively interact with boron sites on p-type particle's surface. As it was shown earlier, for the dispersions 806 and 808 where the nanoparticles were treated with tertiary amine and sulfide respectively, due to Lewis Acid/Lewis Base complex formation between the surface boron atoms and dispersant an average aggregate size is much smaller than for the dispersion 810 in the inert solvent (FIG. 8). However all three dispersions 806, 808 and 810 are characterized by negligibly small peak of organic residue. This confirms temporary nature of Lewis Acid/Lewis Base complex formation between surface acceptor boron atoms and such dispersants as tertiary amines and sulfides, which can be cleanly removed from the surface by heat.

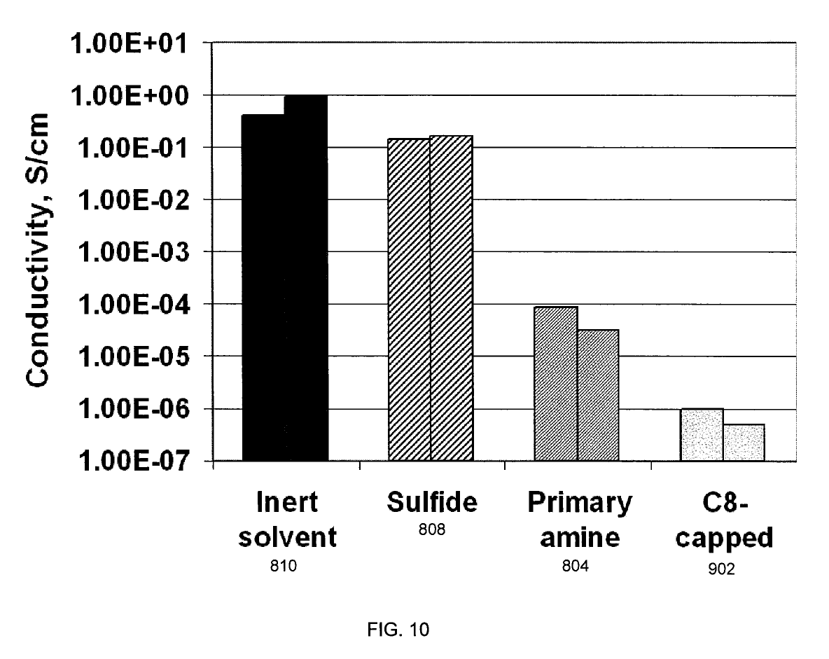

Referring to now to FIG. 10, a simplified diagram showing conductivity for a set of densified films made from various capped and uncapped silicon nanoparticles, in accordance with the invention. Conductivity (shown as S(Siemens)/cm on the vertical axis) is generally measured with a four-point probe. Current is made to flow between the outer probes, and voltage V is measured between the two inner probes, ideally without drawing any current.

Here, the appropriate colloidal dispersion was deposited as a film on dielectric (quartz) substrate. The film was then dried on pre-bake step (at about 60-350° C. from about 5 minutes to about 30 minutes) in order to form a porous compact, as well as remove solvents and capping agents. The porous compact was then heated (at between about 800° C. to about 1000° C. and for about 10 seconds to about 10 minutes) in order to sinter the nanoparticles into a densified film on to which the probes are placed. Consequently, it is believed that the lacking selectivity, the bonded capping agents reduce sinterability and hence conductivity.

As shown in FIG. 10, densified films made from uncapped (inert solvent 810) or complexed with sulfide nanoparticles (dispersion 808) have relatively high conductivity. In contrast, whereas densified films made from partially covalently capped with primary amine particles (dispesion 804) conductivity drops by 3-4 orders, and the conductivity is not measurable for densified films made from covalently capped with ligand C8 nanoparticles (dispersion 902).

For the purposes of this disclosure and unless otherwise specified, “a” or “an” means “one or more.” All patents, applications, references and publications cited herein are incorporated by reference in their entirety to the same extent as if they were individually incorporated by reference. In addition, the word set refers to a collection of one or more items or objects. Furthermore, the inventors believe that similar to p-type Group IV semiconductor surfaces selective capping via interaction of surface boron atoms with capping ligands of LB nature, n-type Group IV semiconductor surfaces can be selectively capped via interaction of surface phosphorus atoms with capping ligands of LA nature such as boranes, aluminum chlorides and organochlorides, etc. In addition, the set of functional groups may have a linear configuration, a branched configuration, or a cyclic configuration.

The invention has been described with reference to various specific and illustrative embodiments. However, it should be understood that many variations and modifications may be made while remaining within the spirit and scope of the invention. Advantages of the invention include the selective functionalization of doped Group IV nanoparticle surfaces.

Having disclosed exemplary embodiments and the best mode, modifications and variations may be made to the disclosed embodiments while remaining within the subject and spirit of the invention as defined by the following claims.

What is claimed is:

1. A method of selectively attaching a capping agent to a Group IV semiconductor surface, comprising:
providing the Group IV semiconductor surface, the Group IV semiconductor surface including a set of covalently bonded Group IV semiconductor atoms and a set of surface boron atoms; and
exposing the set of boron atoms to a set of capping agents, each capping agent of the set of capping agents having a central atom and a set of functional groups, wherein the central atom includes at least a lone pair of electrons;
wherein a complex is formed between at least some surface boron atoms of the set of surface boron atoms and the central atom of at least some capping agents of the set of capping agents.

2. The method of claim 1, wherein at least some of the boron atoms are located at substitutional sites.

3. The method of claim 1, wherein the capping agent is at least one of an amine, a phosphine, an ether, an alcohol, a sulfide or a thiol.

4. The method of claim 1, wherein at least one functional group of the set of functional groups includes hydrogen.

5. The method of claim 1, wherein the Group IV semiconductor surface defines a Group IV semiconductor nanoparticle.

6. The method of claim 1, wherein the Group IV semiconductor nanoparticle is manufactured by one of evaporation, gas phase pyrolysis, gas phase photolysis, electrochemical etching, plasma decomposition of silanes, polysilanes or analogues of other Group IV atoms, or high pressure liquid phase reduction-oxidation reaction.

7. The method of claim 1, wherein the Group IV semiconductor surface is a silicon semiconductor surface.

8. The method of claim 1, wherein no functional group of the set of functional groups includes hydrogen.

9. The method of claim 1, wherein the set of functional groups comprises a linear configuration, a branched configuration, a cyclic configuration, or a combination thereof.

10. The method of claim 1, further comprising heating the Group IV semiconductor surface to a first temperature for about 5 minutes to about 30 minutes, such that the central atom is removed from the surface substitutional boron atom.

11. The method of claim 10, wherein the first temperature is about 60-350° C. and the first time period is about 5 minutes to about 30 minutes.

12. A method of selectively attaching a capping agent to a Group IV semiconductor surface, comprising:
providing the Group IV semiconductor surface, the Group IV semiconductor surface including a set of covalently bonded Group IV semiconductor atoms and a set of surface phosphorous atoms; and
exposing the set of phosphorous atoms to a set of capping agents, each capping agent of the set of capping agents having a central atom and a set of functional groups, wherein the central atom includes at least an empty electron orbital;
wherein a complex is formed between at least some surface phosphorous atoms of the set of surface phosphorous atoms and the central atom of at least some capping agents of the set of capping agents.

13. The method of claim 12, wherein at least some of the phosphorous atoms are located at substitutional sites.

14. The method of claim 12, wherein the capping agent is at least one of an amine or a borane.

15. The method of claim 12, wherein the Group IV semiconductor surface defines a Group IV semiconductor nanoparticle.

16. The method of claim 12, wherein the Group IV semiconductor nanoparticle is manufactured by one of evaporation, gas phase pyrolysis, gas phase photolysis, electrochemical etching, plasma decomposition of silanes, polysilanes, or analogues of other Group IV atoms, or high pressure liquid phase reduction-oxidation reaction.

17. The method of claim 12 wherein the Group IV semiconductor surface is a silicon semiconductor surface.

18. The method of claim 12, wherein the central atom may be removed from the surface substitional boron atom by heating the Group IV semiconductor surface to a first temperature and for a first time period.

19. The method of claim 18, wherein the first temperature is about 60-350° C. and the first time period is about 5 minutes to about 30 minutes.
